(19) United States
(12) Patent Application Publication
(10) Pub. No.: US 2009/0196107 A1
(43) Pub. Date: Aug. 6, 2009

(54) SEMICONDUCTOR DEVICE AND ITS MEMORY SYSTEM

(75) Inventors: Tomohiro Ogasawara, Chuo-ku (JP); Toru Ishikawa, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: Elpida Memory, Inc., Tokyo (JP)

(21) Appl. No.: 12/360,498

(22) Filed: Jan. 27, 2009

(30) Foreign Application Priority Data
Feb. 5, 2008 (JP) 2008-025348

(51) Int. Cl. G11C 7/00

(52) U.S. Cl. 365/189.05; 365/189.011; 365/191

(57) ABSTRACT

A semiconductor device selects one mask pattern among from a plurality of the mask patterns, which are stored in a mask resister circuit for mask controlling of a bit width (vertical axis), by a mask pattern selection signal, and controls input and output of data based on the selected mask pattern and a mask control signal of a bit string (horizontal axis), when inputting and outputting data having the consecutive bit string (horizontal axis) and a plurality of the bit widths (vertical axis). A read data converter circuit and a write data converter circuit select to mask or unmask each data signal during burst reading or writing, and masks the data signal. The masked data signal is not written in a memory cell by inactivating a write data buffer circuit during writing, and is not read out by inactivating a data driver circuit connecting with an external input and output terminal.

### BACKGROUND OF THE INVENTION

1. Field of the Invention

The present invention relates to a semiconductor device and its memory system. More particularly, the present invention relates to a semiconductor device that has a data mask function and the memory system thereof.

Priority is claimed on Japanese Patent Application No. 2008-025348, filed Feb. 5, 2008, the content of which is incorporated herein by reference.

2. Description of Related Art

FIG. 11 shows a part of internal and connecting configurations of a semiconductor memory device that masks data in a write operation, as an example of related art. A data mask portion 700 is connected with an external input terminal of data mask signals DM0 to DM15, and connected with an external input and output terminal of data signals DQ0 to DQ127 with its bit width of 128 bits. The data mask portion 700 includes a plurality of data mask signal latch circuits 71 therein, wherein one of the data mask signal latch circuits 71 is provided to each external input terminal of the data mask signals DM0 to DM15. The data mask portion 700 further includes a plurality of data signal input and output buffer circuits 72, wherein one of the data signal input and output buffer circuits 72 is provided to each group of the external input and output terminal of the data signals DQ0 to DQ127, which has the bit width of 8 bits. A clock signal CLK is input to the data mask signal latch circuit 71 and to the data signal input and output buffer circuits 72.

As shown in FIG. 11, the data signal is made to the groups of several bits so as to control masking or unmasking of the data signal. Thereby, the number of the external input and output terminals needed to mask the data signal is decreased. In this manner, since each of the groups is collectively masked, there is a problem in that it is difficult to mask each bit individually. For example, as shown in FIG. 11, since the external input terminal of the data mask signal is made to the groups having a bit width of 8 bits, and one of the data mask signal latch circuits 71 is provided to each group in the data mask portion 700, it is impossible to individually mask each bit of the same group.

In the example of the related art shown in FIG. 11, the data signals DQ0 to DQ 127, which are input through the external input and output terminal of the data signals DQ0 to DQ127, are input to the data signal input and output buffer circuits 72. The data mask signals DM0 to DM15, which are input through the external input terminal of the data mask signals DM0 to DM15, are input to the data mask signal latch circuits 71. The data signal input and output buffer circuit 72 and the data mask signal latch circuit 71 latch signals input in synchronization with the clock signal CLK, so as to output the latched signals to a memory cell 800. The memory cell 800 stores the data signals DQ0 to DQ 127 input from the data signal input and output buffer circuit 72, based on the data mask signals DM0 to DM15 input from the data mask signal latch circuit 71.

The data signals DQ0 to DQ 127 and the data mask signals DM0 to DM15 are input in the same clock cycle, in synchronization with the clock signal CLK, according to an operation of the related art. The data signal input and output buffer circuit 72 latches the data signals DQ0 to DQ 127 input through the external input and output terminal of the data signals DQ0 to DQ127, and amplifies the latched data signals DQ0 to DQ127, so as to output the amplified data signals DQ0 to DQ127 to the memory cell 800. On the other hand, the data mask signal latch circuit 71 latches the data mask signals DM0 to DM15 input through the external input terminal of the data mask signals DM0 to DM15, so as to output the latched data mask signals DM0 to DM15 to the memory cell 800. The data signals DQ0 to DQ127 are masked in the write operation of the related art. Therefore, the data mask signals DM0 to DM15 reach the memory cell 800 earlier than the data signals DQ0 to DQ127, and hence, the data mask signals DM0 to DM15 cease from the write operation in the related art. For this reason, when the frequency of the clock signal CLK is raised, since the data mask signals DM0 to DM15 have to reach the memory cell 800 earlier than the data signals DQ0 to DQ127, the speed-up of the operation frequency is limited (for example, refer to Japanese Unexamined Patent Application, First Application, No. 2001-351377, No. 2003-151300, and No. 2002-050179).

As mentioned above, in the related art, the external input terminal of the data mask signals DM0 to DM15 is required, and the data signals DQ0 to DQ127 are controlled by grouping. Therefore, the applicants reveal a problem in that it is difficult to individually control each bit of the data signal in the same group.

### SUMMARY

The present invention seeks to solve one or more of the above problems, or to improve those problems at least in part.

In one embodiment, there is provided a semiconductor device for inputting and outputting data having a consecutive bit string and a plurality of bit widths based on a control signal input from outside thereof. The semiconductor device includes a plurality of input and output terminals that corresponds to the bit width of the input and output data, a mask resister circuit that stores a plurality of mask patterns, in advance, corresponding to information to individually mask or unmask each bit of the bit width, and a data converter circuit that masks each bit of the input and output data in accordance with one of the plurality of mask patterns and a mask bit string selection signal, wherein a mask pattern selection signal selects the one mask pattern from among the plurality of mask patterns stored in the mask resister circuit, and the mask bit string selection signal controls masking or unmasking of each bit of the consecutive bit string individually based on the control signal.

In another embodiment, there is provided a semiconductor memory device for inputting and outputting data having a consecutive bit string and a plurality of bit widths to outside thereof. The semiconductor memory device includes a plurality of input and output terminals that corresponds to the bit width of the input and output data, a input and output circuit that inputs and outputs the data, and is connected with the plurality of input and output terminals, a write circuit and a read circuit that are connected with the input and output circuit, and communicate with a plurality of memory cells, a mask resister circuit that stores a mask pattern of first information to individually mask or unmask each bit of the bit width, and a data mask signal generation circuit that generates a mask bit string selection signal of second information to individually mask or unmask each bit of the bit string, wherein the mask pattern and the mask bit string selection signal are input to the write circuit and the read circuit, and the data is input and output by mask controlling in accordance with the mask pattern and the mask bit string selection signal.

In another embodiment, there is provided a control method of a semiconductor memory device for inputting and outputting data having a consecutive bit string and a plurality of bit widths to outside thereof. The control method includes generating a mask pattern selection signal that selects one mask pattern from among a plurality of the mask patterns, wherein the mask pattern corresponds to first information to individually mask or unmask each bit of the bit width, generating a mask bit string selection signal that corresponds to second information to individually mask or unmask each bit of the bit string, and communicating a write circuit and a read circuit, which communicate with a plurality of memory cells, with the memory cell or the semiconductor memory device based on a control signal input from outside of the semiconductor memory device, wherein the write circuit and the read circuit communicate data except individually masked data among the inputting and outputting data to the memory cell or the semiconductor memory device, in accordance with the generated mask pattern selection signal and the generated mask bit string selection signal.

In another embodiment, there is provided a memory system for inputting and outputting data having a consecutive bit string and a plurality of bit widths. The memory system includes a memory controller and a memory device that input and output the data therebetween and a plurality of command buses and a plurality of input and output (I/O) buses that connect the memory controller with the memory device, wherein the memory controller includes a control signal generation circuit and a data process circuit and the control signal generation circuit and the data process circuit output selection information that selects necessary command and address to access the memory device, second mask information of the bit string, and a plurality of first mask information of the bit width.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a block diagram that shows a part of internal and connecting configurations of a circuit related to input and output of a data signal, and provided in DDR-SDRAM according to a first embodiment of the present invention;

FIG. 2 is a block diagram that shows a part of the internal and connecting configurations of the circuit related to input and output of the data signal, and provided in DDR-SDRAM according to the first embodiment of the present invention, where a mask resister is provided at each external input and output terminal of data signals from DQ0 to DQ15;

FIG. 3 is a timing chart that shows a storage operation of the mask resister according to the first embodiment of the present invention;

FIG. 4 is a timing chart that shows data masking in a write operation according to the first embodiment of the present invention;

FIG. 5 is a table that shows mask pattern signals stored in the mask resisters provided in a mask resister circuit, and is used in explanations of read and write operations according to the first and a second embodiments of the present invention;

FIG. 6 is a timing chart that shows the data masking in a read operation according to the first embodiment of the present invention;

FIG. 7 is a block diagram that shows a part of internal and connecting configurations of a circuit related to input and output of a data signal, and provided in DDR-SDRAM according to the second embodiment of the present invention;

FIG. 8 is a block diagram that shows a part of the internal and connecting configurations of the circuit related to input and output of the data signal, and provided in DDR-SDRAM according to the second embodiment of the present invention, where a mask resister is provided at each external input and output terminal of data signals from DQ0 to DQ15;

FIG. 9 is a timing chart that shows data masking in a write operation according to the second embodiment of the present invention;

FIG. 10 is a timing chart that shows the data masking in a read operation according to the second embodiment of the present invention;

FIG. 11 is a block diagram that shows a part of internal and connecting configurations of a semiconductor memory device for data masking in a write operation according to a related art; and

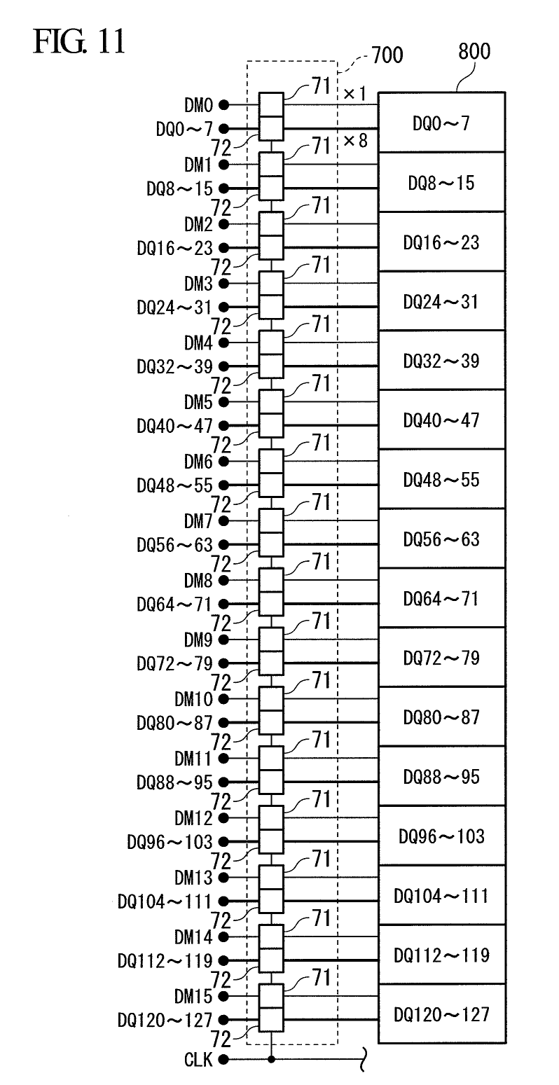

FIG. 12 is a block diagram that shows the configuration of the semiconductor memory device and a memory system including a memory controller of the semiconductor memory device.

### DETAILED DESCRIPTION OF PREFERRED EMBODIMENTS

The invention will be described herein with reference to illustrative embodiments. Those skilled in the art will recognize that many alternative embodiments can be accomplished using the teachings of the present invention and that the invention is not limited to the embodiments illustrated herein for explanatory purposes.

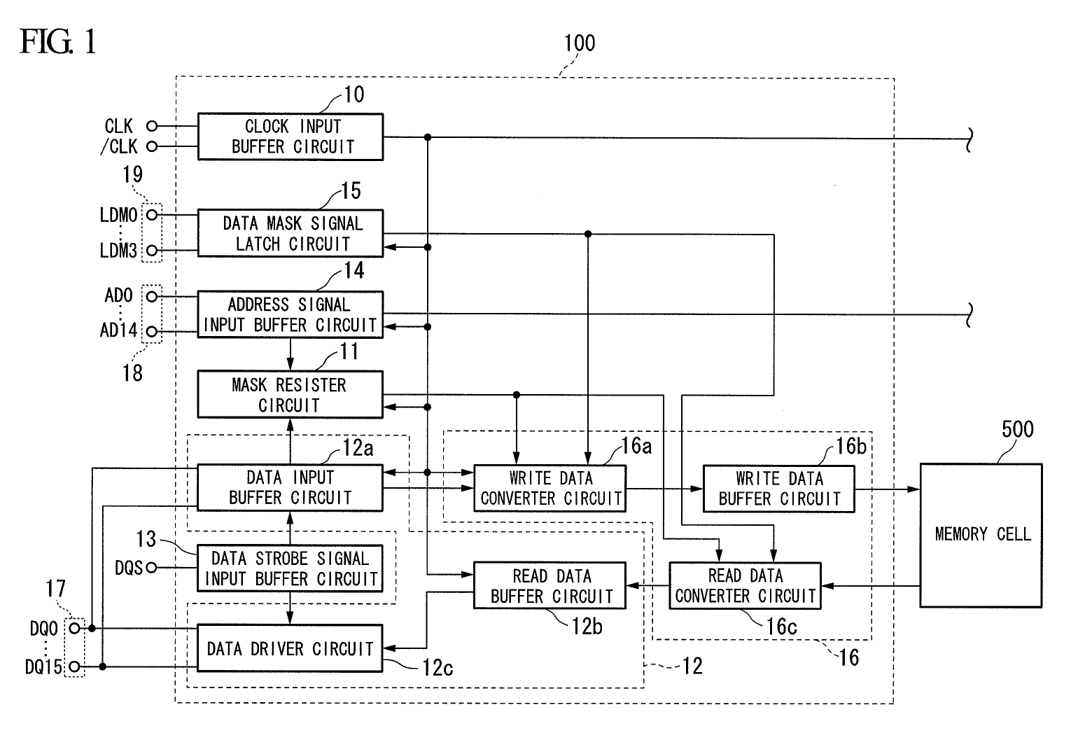

An example, in which a semiconductor device of the present invention is applied to a double data rate synchronous dynamic random access memory (DDR-SDRAM), will be described hereinbelow, with reference to FIG. 1 to FIG. 10. In the embodiments, input and output data signals have a bit width (vertical axis) of 16 bits, an address signal has a 15-bit width, and a burst length of a bit string (horizontal axis) is 4.

### First Embodiment

FIG. 1 shows an internal configuration of a data mask portion 100 that relates to input and output of the data signal, and its connecting configuration with a memory cell 500, which are provided in DDR-SDRAM according to a first embodiment of the present invention.

A clock input buffer circuit 10 amplifies clock signals which are input through external input terminals of a clock signal CLK and a clock signal /CLK. The clock input buffer circuit 10 outputs the amplified clock signals to a data mask signal latch circuit 15, an address signal input buffer circuit (mask pattern selection signal latch circuit) 14, a mask resister circuit 11, a data input buffer circuit 12a, a read data buffer circuit 12b, a data driver circuit 12c, a write data converter circuit 16a, a write data buffer circuit 16b, a read data converter circuit 16c, and outside of the data mask portion 100.

The mask resister circuit 11 outputs mask pattern signals DM0 to DM15, which are stored in a mask resister provided therein, to the write data converter circuit 16a and the read data converter circuit 16c in a mask operation, based on a mask resister selection signal input from the address signal input buffer circuit 14. The mask resister circuit 11 stores data signals DQ0 to DQ15 input from the data input buffer circuit 12a in the mask resister provided therein, as the mask pattern signals DM0 to DM15, selected by the mask resister selection signal input from the address signal input buffer circuit 14, in an update operation of the mask resister. The mask resister circuit 11 includes a mask resister 0, a mask resister 1, a mask resister 2, and a mask resister 3, each having a bit width of 16 bits.

The mask resister circuit 11 inputs, in advance, the mask pattern signals DM0 to DM15 to be stored therein through an external terminal described hereinafter (input and output terminal, in other words, external input and output terminal 17 of the data signals DQ0 to DQ15).

The data input and output buffer circuit (input and output circuit) 12 includes the data input buffer circuit 12a, the read data buffer circuit 12b, and the data driver circuit 12c.

The data input buffer circuit 12a reads the data signals DQ0 to DQ15 through an external input and output terminal (input and output terminal) 17 of the data signals DQ0 to DQ15, in synchronization with transition of a data strobe signal DQS input from a data strobe signal input buffer circuit 13. The data input buffer circuit 12a amplifies the read data signals DQ0 to DQ15 so as to output the amplified data signals DQ0 to DQ15 to the write data converter circuit 16a and the mask resister circuit 11.

The read data buffer circuit 12b, to which the data signals DQ0 to DQ15 are input from the read data converter circuit 16c, amplifies the input data signals DQ0 to DQ15 so as to output the amplified data signals DQ0 to DQ15 to the data driver circuit 12c.

The data driver circuit 12c reads the data signals DQ0 to DQ15 through the read data buffer circuit 12b, in synchronization with the transition of the data strobe signal DQS input from the data strobe signal input buffer circuit 13. The data driver circuit 12c amplifies the read data signals DQ0 to DQ15 so as to output the amplified data signals DQ0 to DQ15 to the external input and output terminal (input and output terminal) 17 of the data signals DQ0 to DQ15.

The data strobe signal input buffer circuit 13 amplifies the data strobe signal DQS input through an input terminal of the data strobe signal DQS, so as to output the amplified data strobe signal DQS to the data input buffer circuit 12a and the data driver circuit 12c.

The address signal input buffer circuit (mask pattern selection signal latch circuit) 14 amplifies address signals AD0 to AD14 input through an external input terminal (first external terminal) 18 of the address signals AD0 to AD14, so as to output the amplified address signals AD0 to AD14 to the outside of the data mask portion 100, in order to select the memory cell 500. As is described hereinafter, the address signal input buffer circuit (mask pattern selection signal latch circuit) 14 outputs a mask pattern selection signal that selects one of the plural mask patterns. When a mode resister set (MRS) command is input to DDR-SDRAM in synchronization with the transition of the clock signal CLK, and further an “H” (high level) is input to the terminals AD13 and AD14 among the external input terminal 18 of the address signals AD0 to AD14, the address signal input buffer circuit 14 decodes a signal of the least significant two bits of a mask instruction signal input thereto. The signal of the least significant two bits of the mask instruction signal correspond to the signals input through terminals corresponding to the address signals AD0 and AD1 among the external input terminal 18 of the address signals AD0 to AD14. The address signal input buffer circuit (mask pattern selection signal latch circuit) 14 has an address function that selects a memory cell in the memory cell 500.

The address signal input buffer circuit 14 decodes the signal of the least significant two bits of the mask instruction signal input through the terminals corresponding to the address signals AD0 and AD1 among the external input terminal 18 of the address signals AD0 to AD14 in a clock cycle after a write command or a read command is input to DDR-SDRAM. The address signal input buffer circuit 14 generates the mask resister selection signal which selects the mask resisters 0 to 3 provided in the mask resister circuit 11 by using the decoded result, so as to output the generated mask resister selection signal to the mask resister circuit 11.

The data mask signal latch circuit (data mask signal generation circuit) 15 latches data mask signals LDM0 to LDM3 input through an external input terminal (second external terminal) 19 of the data mask signals LDM0 to LDM3. The data mask signal latch circuit 15 outputs a signal for controlling the mask operation (hereinafter refer to mask control signal, or mask bit string selection signal) to the write data converter circuit 16a and the read data converter circuit 16c, based on the latched data mask signals LDM0 to LDM3.

The data mask signals LDM0, LDM1, LDM2, and LDM3 control and select masking or unmasking of a first, a second, a third, and a fourth data signals DQ0 to DQ15, when the burst length is 4. For example, when the data mask signal LDM0 is an “H”, the first data signals DQ0 to DQ15 are masked. On the other hand, when the data mask signal LDM0 is an “L”, the first data signals DQ0 to DQ15 are not masked. As is the case with this, the data mask signal LDM1 corresponds to the second data signals DQ0 to DQ15, the data mask signal LDM2 corresponds to the third data signals DQ0 to DQ15, and the data mask signal LDM3 corresponds to the fourth data signals DQ0 to DQ15, so as to control and select masking or unmasking of the data signal.

A data converter circuit 16 includes the write data converter circuit 16a, the write data buffer circuit 16b, and the read data converter circuit 16c.

The mask control signal is input to the write data converter circuit 16a from the data mask signal latch circuit 15. The mask pattern signals DM0 to DM15 are input to the write data converter circuit 16a from the mask resister circuit 11. The data signals DQ0 to DQ15 are input to the write data converter circuit 16a from the data input buffer circuit 12a. The write data converter circuit 16a converts the input data signals DQ0 to DQ15 by using the input mask pattern signals DM0 to DM15, based on the input mask control signal. That is, the data converter circuit 16 controls masking or unmasking of a data bit transferring between the data input buffer circuit 12a and the write data buffer circuit 16b, in accordance with the mask pattern signals DM0 to DM15 and the mask control signal (mask bit string selection signal), in which the mask pattern signals DM0 to DM15 controls which input and output terminals are masked or unmasked among the bit width of data (vertical axis) corresponding to the plurality of the input and output terminals and the mask control signal (mask bit string selection signal) controls which positions of the bit string are masked or unmasked among the bit string of the consecutive data (horizontal axis) corresponding to one input and output terminal. The write data converter circuit 16a outputs the converted data signals to the write data buffer circuit 16b, as the data signals DQ0 to DQ15.

In the conversion made by the write data converter circuit 16a, the input corresponds to the data signals DQ0 to DQ15, while the output corresponds to the masked data signals DQ0 to DQ15 or the unmasked data signals DQ0 to DQ15. The converted (masked or unmasked) output is selected by the mask control signal input from the data mask signal latch circuit 15. Each bit is individually masked in response to the value (bit pattern) of the mask pattern signals DM0 to DM15. Each bit of the mask pattern signals corresponds to each bit of the data signals, that is, DM0 corresponds to DQ0, DM1 corresponds to DQ1, DM2 corresponds to DQ2, . . . and DM15 corresponds to DQ15. When DMn (n=0, 1, . . . and 15) is an “H”, the corresponding DQn (n=0, 1, . . . and 15) is masked. On the other hand, when DMn (n=0, 1, . . . and 15) is “L”, the corresponding DQn (n=0, 1, . . . and 15) is not masked.

The write data buffer circuit 16b, in which the data signals DQ0 to DQ15 are input from the write data converter circuit 16a, amplifies the input data signals DQ0 to DQ15 so as to output the amplified data signals DQ0 to DQ15 to the memory cell 500. The write data buffer circuit 16b has a write amplifier function.

The mask control signal is input to the read data converter circuit 16c from the data mask signal latch circuit 15. The mask pattern signals DM0 to DM15 are input to the read data converter circuit 16c from the mask resister circuit 11. The data signals DQ0 to DQ15 are input to the read data converter circuit 16c from the memory cell 500. The read data converter circuit 16c converts the input data signals DQ0 to DQ15 by using the input mask pattern signals DM0 to DM15, based on the input mask control signal. The read data converter circuit 16c outputs the data signals, which are similarly converted by the write data converter circuit 16a, to the read data buffer circuit 12b, as the data signals DQ0 to DQ15.

The write data converter circuit 16a and the write data buffer circuit 16b are an inseparable circuit in a writing communication between the memory cell 500 and the data input buffer circuit 12a, and are called a write circuit.

The read data converter circuit 16c and the read data buffer circuit 12b are the inseparable circuit in a readout communication between the memory cell 500 and the data driver circuit 12c, and are called a read circuit.

The read data converter circuit 16c may be placed between the read data buffer circuit 12b and the data driver circuit 12c.

The memory cell 500 stores the data signals DQ0 to DQ15 which are input from the write data buffer circuit 16b during the write operation, and outputs the stored data signals DQ0 to DQ15 to the read data converter circuit 16c during the read operation, based on a control signal input through another external input terminal provided in DDR-SDRAM.

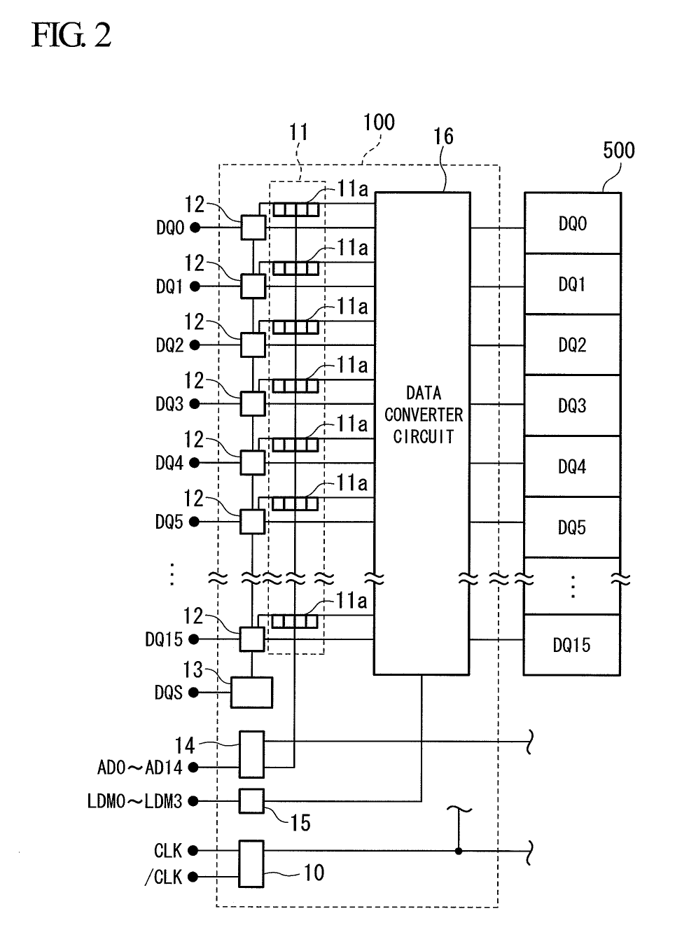

FIG. 2 shows the data mask portion 100 according to the first embodiment of the present invention, in which a mask resister circuit 11a is provided at each external input and output terminal 17 of the data signals DQ0 to DQ15.

As shown in FIG. 2, the mask resister circuit 11 includes 16 pieces of the mask resister circuit 11a therein, which is placed at each external input and output terminal of the data signals DQ0 to DQ15. The mask resister circuit 11a outputs the signal stored in a mask resister provided therein to the data converter circuit 16, as the mask pattern signal DM, based on the input mask resister selection signal, in the mask operation. The mask resister circuit 11a stores the input data signal DQ in the mask resister selected by the mask resister selection signal input from the address signal input buffer circuit 14, in the update operation of the mask resister provided in its own. The mask resister circuit 11a includes the mask resister having 4 bits, and each bit is assigned to an address 0, an address 1, an address 2, and an address 3. The mask resister provided in the mask resister circuit 11a composes the mask resisters 0 to 3 by making the 16 pieces of mask resister with the same identifier to be one set. That is, a set of bits identified as address 0 composes the mask resister 0, the set of bits identified as address 1 composes the mask resister 1, the set of bits identified as address 2 composes the mask resister 2, and the set of bits identified as address 3 composes the mask resister 3.

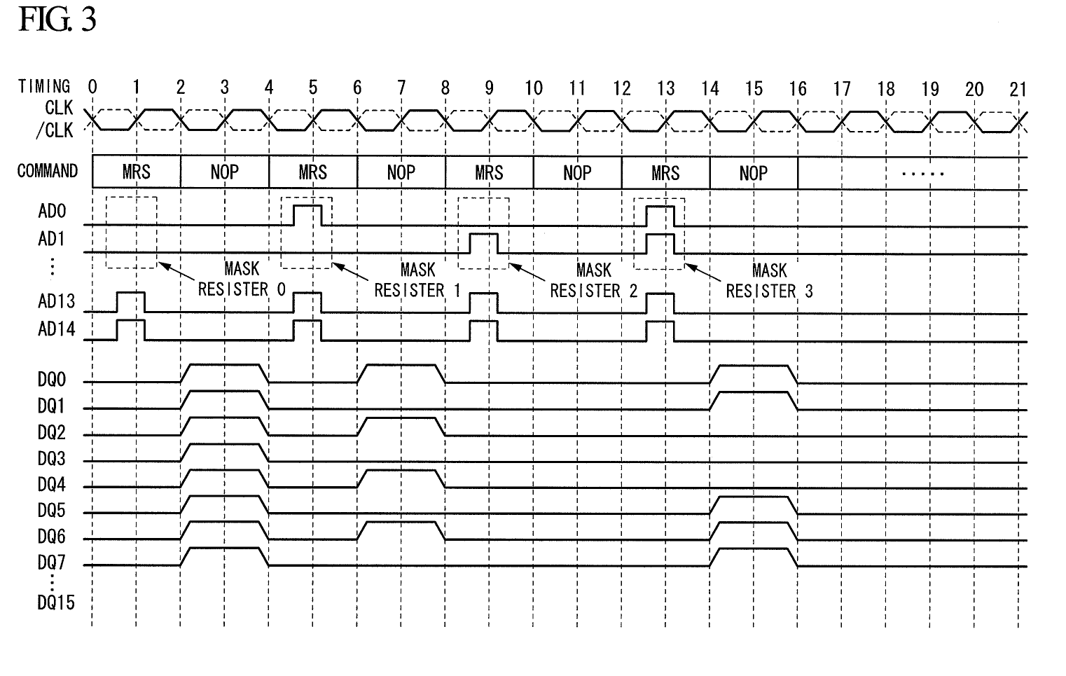

FIG. 3 shows a timing chart that explains operation of storing the mask pattern signals DM0 to DM 15 according to the first embodiment of the present invention.

In the explanation of the storage operation, signal levels are described by an “H” and an “L”, where the “H” corresponds to the signal placed in a high level while the “L” corresponds to the signal placed in a low level.

### Storage Operation of Mask Resister

### EXAMPLE 1

The MRS command is input, and further an “HH” is input through the external input terminals corresponding to AD13 and AD14 among the external input terminal 18 of the address signals AD0 to AD14, at a timing of 1. The address signal input buffer circuit 14 decodes the signal of the least significant two bits of the mask instruction signal read from the external input terminal 18 of the address signals AD0 to AD14. At the timing of 1, (AD0, AD1)=(L, L) indicates the mask resister 0 provided in the mask resister circuit 11. The address signal input buffer circuit 14 generates the mask resister selection signal which controls the update operation of the mask resister 0 provided in the mask resister circuit 11 by using the decoded result, so as to output the generated mask resister selection signal to the mask resister circuit 11.

A data signal of “HHHH . . . HH”, which indicates the mask pattern, is input through the external input terminal 17 of the data signals DQ0 to DQ15 at a timing of 3. The data input buffer circuit 12a amplifies the data signal indicating the mask pattern, in synchronization with the transition of the data strobe signal DQS input from the data strobe signal input buffer circuit 13, so as to output the amplified data signal to the mask resister circuit 11. The mask resister circuit 11 stores the data signal of “HHHH . . . HH” in the mask resister 0 provided therein, based on the mask resister selection signal input from the address signal input buffer circuit 14 and the data signal input from the data input buffer circuit 12a.

### Storage Operation of Mask Resister

### EXAMPLE 2

The MRS command is input, and further an “HH” is input through the external input terminals corresponding to AD13 and AD14 among the external input terminal 18 of the address signals AD0 to AD14, at a timing of 5. The address signal input buffer circuit 14 decodes the signal of the least significant two bits of the mask instruction signal read from the external input terminal 18 of the address signals AD0 to AD14. At the timing of 5, (AD0, AD1)=(H, L) indicates the mask resister 1 provided in the mask resister circuit 11. The address signal input buffer circuit 14 generates the mask resister selection signal which controls the update operation of the mask resister 1 provided in the mask resister circuit 11 by using the decoded result, so as to output the generated mask resister selection signal to the mask resister circuit 11.

The data signal of “HLHL . . . HL”, which indicates the mask pattern, is input through the external input terminal 17 of the data signals DQ0 to DQ15 at a timing of 7. The data input buffer circuit 12a amplifies the data signal indicating the mask pattern, in synchronization with the transition of the data strobe signal DQS input from the data strobe signal input buffer circuit 13, so as to output the amplified data signal to the mask resister circuit 11. The mask resister circuit 11 stores the data signal of “HLHL . . . HL” in the mask resister 1 provided therein, based on the mask resister selection signal input from the address signal input buffer circuit 14 and the data signal input from the data input buffer circuit 12a.

### Storage Operation of Mask Resister

### EXAMPLE 3

The MRS command is input, and further an “HH” is input through the external input terminals corresponding to AD13 and AD14 among the external input terminal 18 of the address signals AD0 to AD14, at a timing of 9. The address signal input buffer circuit 14 decodes the signal of the least significant two bits of the mask instruction signal read from the external input terminal 18 of the address signals AD0 to AD14. At the timing of 9, (AD0, AD1)=(L, H) indicates the mask resister 2 provided in the mask resister circuit 11. The address signal input buffer circuit 14 generates the mask resister selection signal which controls the update operation of the mask resister 2 provided in the mask resister circuit 11 by using the decoded result, so as to output the generated mask resister selection signal to the mask resister circuit 11.

The data signal of “LLLL . . . LL”, which indicates the mask pattern, is input through the external input terminal 17 of the data signals DQ0 to DQ15 at a timing of 11. The data input buffer circuit 12a amplifies the data signal indicating the mask pattern, in synchronization with the transition of the data strobe signal DQS input from the data strobe signal input buffer circuit 13, so as to output the amplified data signal to the mask resister circuit 11. The mask resister circuit 11 stores the data signal of “LLLL . . . LL” in the mask resister 2 provided therein, based on the mask resister selection signal input from the address signal input buffer circuit 14 and the data signal input from the data input buffer circuit 12a.

### Storage Operation of Mask Resister

### EXAMPLE 4

The MRS command is input, and further an “HH” is input through the external input terminals corresponding to AD13 and AD14 among the external input terminal 18 of the address signals AD0 to AD14, at a timing of 13. The address signal input buffer circuit 14 decodes the signal of the least significant two bits of the mask instruction signal read from the external input terminal 18 of the address signals AD0 to AD14. At the timing of 13, (AD0, AD1)=(H, H) indicates the mask resister 3 provided in the mask resister circuit 11. The address signal input buffer circuit 14 generates the mask resister selection signal which controls the update operation of the mask resister 3 provided in the mask resister circuit 11 by using the decoded result, so as to output the generated mask resister selection signal to the mask resister circuit 11.

The data signal of “HHLLLHHH . . . ”, which indicates the mask pattern, is input through the external input terminal 17 of the data signals DQ0 to DQ15 at a timing of 15. The data input buffer circuit 12a amplifies the data signal indicating the mask pattern, in synchronization with the transition of the data strobe signal DQS input from the data strobe signal input buffer circuit 13, so as to output the amplified data signal to the mask resister circuit 11. The mask resister circuit 11 stores the data signal of “HHLLLHHH . . . ” in the mask resister 3 provided therein, based on the mask resister selection signal input from the address signal input buffer circuit 14 and the data signal input from the data input buffer circuit 12a.

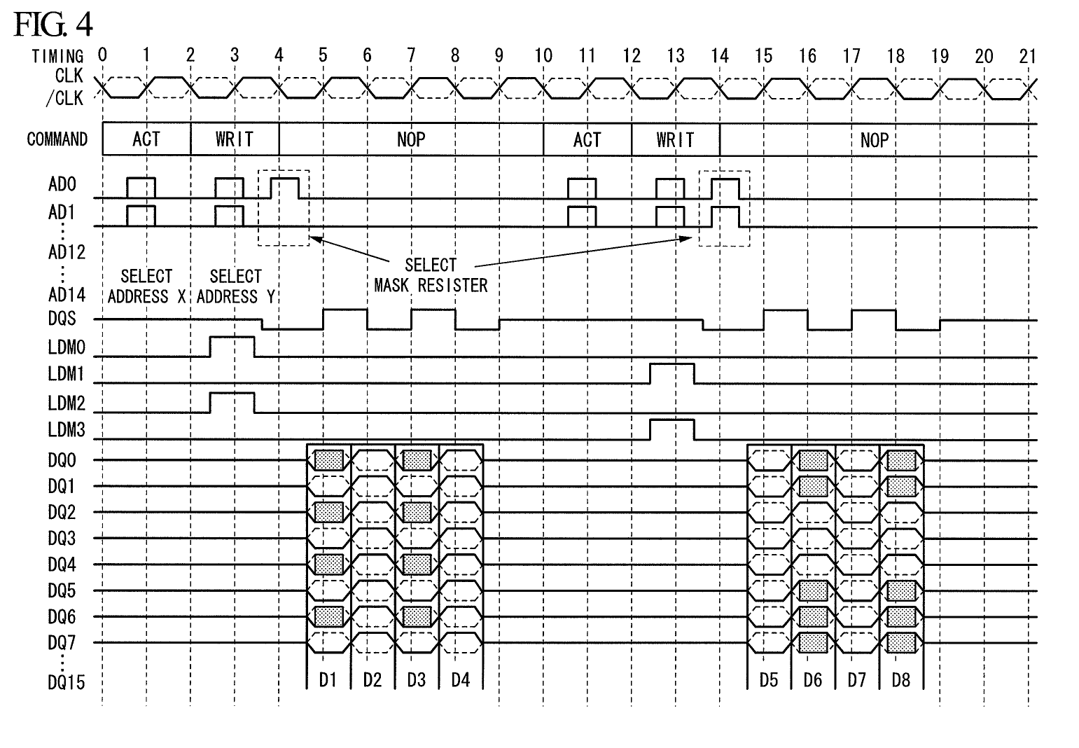

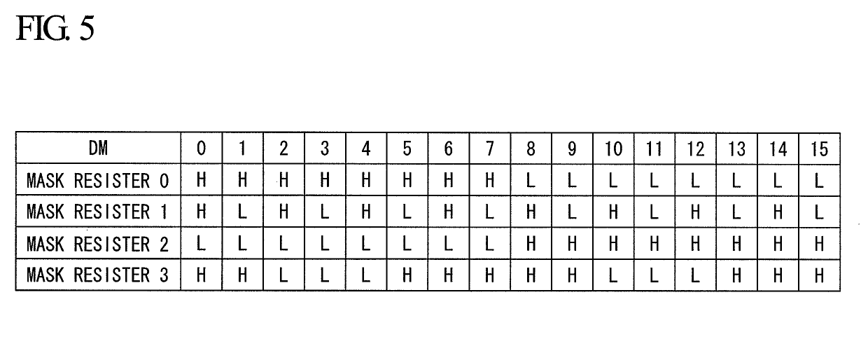

Subsequently, FIG. 4 shows a timing chart that explains the mask in the write operation according to the first embodiment of the present invention. In this write operation, the mask resister provided in the mask resister circuit 11 is assumed to store the value (bit pattern) of the mask pattern signals DM0 to DM15 shown in FIG. 5 in advance.

### Mask in Write Operation

### EXAMPLE 1

An active (ACT) command is input, and further a row address signal is input through the external input terminals 18 of the address signals AD0 to AD14, at a timing of 1. A write command (refer to WRIT in FIG. 4) is input, a column address signal is input through the external input terminals 18 of the address signals AD0 to AD14, and further the data mask signals LDM0 to LDM3 are input through the external input terminals 19 of the data mask signals LDM0 to LDM3, at a timing of 3. In this case, (LDM0, LDM 1, LDM2, LDM3)=(H, L, H, L) indicates that a first write data signal D1 (at a timing of 5) and a third write data signal D3 (at a timing of 7), which correspond to the write command WRIT, are masked. The data mask signal latch circuit 15 generates the mask control signal, which controls masking of the first and third write data, in accordance with the data mask signals LDM0 to LDM3 read at the timing of 3, so as to output the generated mask control signal to the write data converter circuit 16a.

The address signal input buffer circuit 14 reads the mask instruction signal from the external input terminal 18 of the address signals AD0 to AD14 at a timing of 4. The address signal input buffer circuit 14 decodes the signal of the least significant two bits of the read mask instruction signal, so as to generate the mask resister selection signal which selects the mask resister provided in the mask resister circuit 11. In this case, (AD0, AD1)=(H, L) indicates that the mask pattern signal stored in the mask resister 1 is employed to mask the data signal.

The address signal input buffer circuit 14 generates the mask resister selection signal which includes an instruction to output the mask pattern signals DM0 to DM15 stored in the mask resister 1 provided in the mask resister circuit 11 by using the decoded result, so as to output the generated mask resister selection signal to the mask resister circuit 11.

The mask resister circuit 11 outputs the mask pattern signals DM0 to DM15 stored in the mask resister 1 to the write data converter circuit 16a, based on the mask address selection signal input from the address signal input buffer circuit 14. As shown in FIG. 5, the mask resister 1 stores the data signal of “HLHL . . . HL”. This indicates that the corresponding DQ0, DQ2, DQ4, DQ6, DQ8, DQ10, DQ12, and DQ14 are masked.

The data input buffer circuit 12a reads the data signals DQ0 to DQ15 at timings of 5, 6, 7, and 8, in synchronization with the transition of the data strobe signal DQS input from the data strobe signal input buffer circuit 13. The data input buffer circuit 12a amplifies the read data signals DQ0 to DQ15 so as to output the amplified data signals DQ0 to DQ15 to the write data converter circuit 16a.

The write data converter circuit 16a converts the data signals DQ0 to DQ15 input from the data input buffer circuit 12a, by using the mask pattern signals DM0 to DM15 input from the mask resister circuit 11, based on the mask control signal input from the data mask signal latch circuit 15. The write data converter circuit 16a outputs the converted data signals DQ0 to DQ15 to the write data buffer circuit 16b. The write data buffer circuit 16b amplifies the data signals DQ0 to DQ15 input from the write data converter circuit 16a so as to output the amplified data signals DQ0 to DQ15 to the memory cell 500.

Therefore, the masked write data signal D1, a write data signal D2, the masked write data signal D3, and a write data signal D4 are stored in the memory cell 500.

In this manner, operation, in which the masked write data signals D1 and D3 are stored in the memory cell 500, indicates that the write data buffer circuit 16b does not operate (in other words, inactive control), and hence, past record data of the corresponding memory cell is maintained.

The present application discloses a bit string mask signal (mask bit string selection signal) which is controlled by the data mask signal LDM, and a mask pattern signal which is controlled by the mask resister circuit, wherein the bit string mask signal indicates which positions of the consecutive bit string (burst length) are masked or unmasked, and the mask pattern signal indicates which positions of an input and output (I/O) signal (data signal DQ) are masked or unmasked. The present application further discloses the mask pattern selection signal (mask resister instruction signal) that selects one of the plural mask patterns.

According to the first embodiment of the present invention, the write data converter circuit 16a includes a logic control circuit (unillustrated) that carries out an AND operation of the bit string mask signal and the mask pattern signal. In this manner, for example, DQ0 in the write data signal D2, which indicates the second of the bit string, is not masked, and DQ1 in the write data signal D1, which indicates the first of the bit string, is not masked, as shown in the timings 5 to 8 in FIG. 4. On the other hand, DQ0, DQ2, DQ4, DQ6, DQ8, DQ10, DQ12, and DQ14, which correspond to the data signal stored in the mask resister 1, in the write signals D1 and D3 are selectively masked.

This logic control circuit decides a timing at which bit string mask information (mask bit string selection signal) is applied, and makes the bit string mask information (mask bit string selection signal) to be prior to the mask pattern signals DM0 to DM15.

The logic control may be modified as described hereinafter.

In a first application example according to the first embodiment of the present invention, the write data converter circuit 16a includes a logic control circuit that makes the bit string mask signal logically prior to the mask pattern signal. In this manner, all the data signals DQ0 to DQ15 at the first and third of the bit string D1 and D3 are masked.

In a second application example according to the first embodiment of the present invention, the write data converter circuit 16a includes a logic control circuit that makes the mask pattern signal logically prior to the bit string mask signal. In this manner, DQ0, DQ2, DQ4, DQ6, DQ8, DQ10, DQ12, and DQ14, which correspond to the data signal stored in the mask resister 1, in the write signals D1 to D4 are masked.

The logic control circuit may generate mask logic by incorporating further information such as a resister and the like, in a rational manner.

Although the logic control in the write data converter circuit 16a will be described by using the AND logic, in the under-mentioned explanation of the embodiment, the invention is not to be considered as being limited by this explanation.

### Mask in Write Operation

### EXAMPLE 2

The ACT command is input, and further the row address signal is input through the external input terminals 18 of the address signals AD0 to AD14, at a timing of 11. The write command WRIT is input, the column address signal is input through the external input terminals 18 of the address signals AD0 to AD14, and further the data mask signals LDM0 to LDM3 are input through the external input terminals 19 of the data mask signals LDM0 to LDM3, at a timing of 13. In this case, (LDM0, LDM 1, LDM2, LDM3)=(L, H, L, H) indicates that a second write data signal D6 (at a timing of 16) and a fourth write data signal D8 (at a timing of 18), which correspond to the write command WRIT, are masked. The data mask signal latch circuit 15 generates the mask control signal, which controls masking of the second and fourth write data, in accordance with the data mask signals LDM0 to LDM3 read at the timing of 13, so as to output the generated mask control signal to the write data converter circuit 16a.

The address signal input buffer circuit 14 reads the mask instruction signal from the external input terminal 18 of the address signals AD0 to AD14 at a timing of 14. The address signal input buffer circuit 14 decodes the signal of the least significant two bits of the read mask instruction signal, so as to generate the mask resister selection signal which selects the mask resister provided in the mask resister circuit 11. In this case, (AD0, AD1)=(H, H) indicates that the mask pattern signal stored in the mask resister 3 is employed to mask the data.

The address signal input buffer circuit 14 generates the mask resister selection signal which includes the instruction to output the mask pattern signals DM0 to DM15 stored in the mask resister 3 provided in the mask resister circuit 11 by using the decoded result, so as to output the generated mask resister selection signal to the mask resister circuit 11.

The mask resister circuit 11 outputs the mask pattern signals DM0 to DM15 stored in the mask resister 3 to the write data converter circuit 16a, based on the mask address selection signal input from the address signal input buffer circuit 14. As shown in FIG. 5, the mask resister 3 stores the data signal of “HHLLLHHHHHLLLHHH”. This indicates that the corresponding DQ0, DQ1, DQ5, DQ6, DQ7, DQ8, DQ9, DQ13, DQ14, and DQ15 are masked.

The data input buffer circuit 12a reads the data signals DQ0 to DQ15 at timings of 15, 16, 17, and 18, in synchronization with the transition of the data strobe signal DQS input from the data strobe signal input buffer circuit 13. The data input buffer circuit 12a amplifies the read data signals DQ0 to DQ15 so as to output the amplified data signals DQ0 to DQ15 to the write data converter circuit 16a.

The write data converter circuit 16a converts the data signals DQ0 to DQ15 input from the data input buffer circuit 12a, by using the mask pattern signals DM0 to DM15 input from the mask resister circuit 11, based on the mask control signal input from the data mask signal latch circuit 15. The write data converter circuit 16a outputs the converted data signals DQ0 to DQ15 to the write data buffer circuit 16b. The write data buffer circuit 16b amplifies the data signals DQ0 to DQ15 input from the write data converter circuit 16a so as to output the amplified data signals DQ0 to DQ15 to the memory cell 500.

Therefore, a write data signal D5, the masked write data signal D6, a write data signal D7, and the masked write data signal D8 are stored in the memory cell 500.

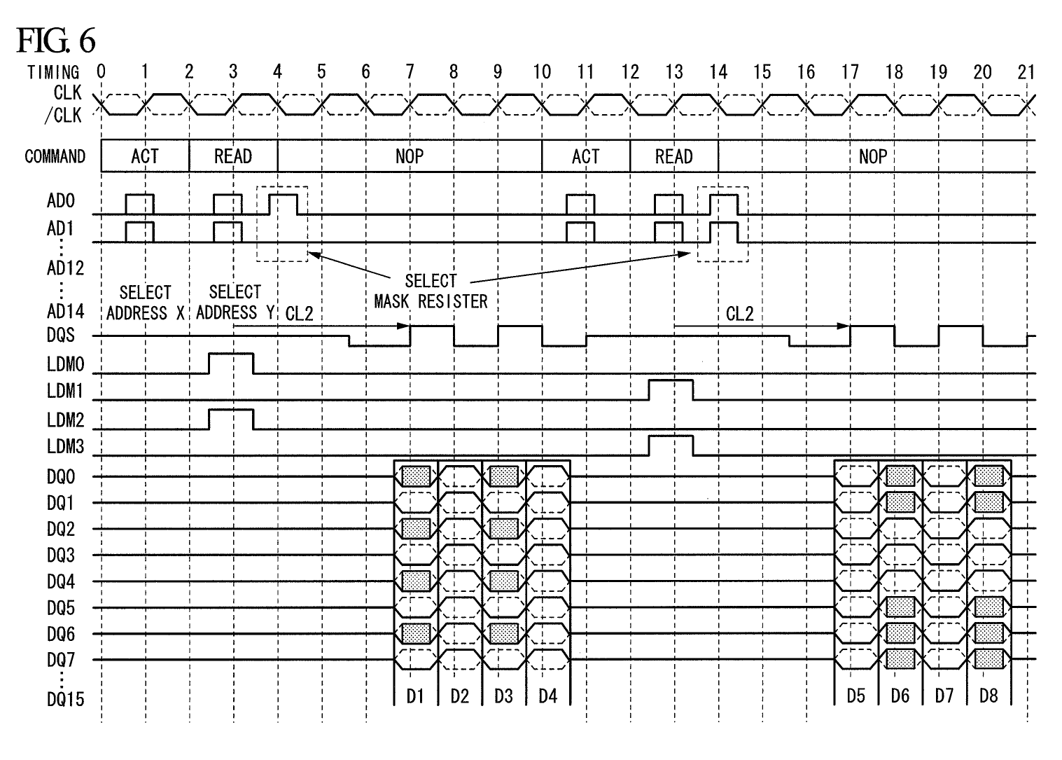

Subsequently, FIG. 6 shows a timing chart that explains the mask in the read operation according to the first embodiment of the present invention. In this read operation, the mask resister provided in the mask resister circuit 11 is assumed to store the value (bit pattern) of the mask pattern signals DM0 to DM15 shown in FIG. 5 in advance.

### Mask in Read Operation

### EXAMPLE 1

The ACT command is input, and further the row address signal is input through the external input terminals 18 of the address signals AD0 to AD14, at a timing of 1. A read command (refer to READ in FIG. 6) is input, the column address signal is input through the external input terminals 18 of the address signals AD0 to AD14, and further the data mask signals LDM0 to LDM3 are input through the external input terminals 19 of the data mask signals LDM0 to LDM3, at a timing of 3. In this case, (LDM0, LDM 1, LDM2, LDM3)=(H, L, H, L) indicates that a first read data signal D1 (at a timing of 7) and a third read data signal D3 (at a timing of 9), which correspond to the read command READ, are masked. The data mask signal latch circuit 15 generates the mask control signal, which controls masking of the first and third read data, in accordance with the data mask signals LDM0 to LDM3 read at the timing of 3, so as to output the generated mask control signal to the read data converter circuit 16c.

The address signal input buffer circuit 14 reads the mask instruction signal from the external input terminal 18 of the address signals AD0 to AD14 at a timing of 4. The address signal input buffer circuit 14 decodes the signal of the least significant two bits of the read mask instruction signal, so as to generate the mask resister selection signal which selects the mask resister provided in the mask resister circuit 11. In this case, (AD0, AD1)=(H, L) indicates that the mask pattern signal stored in the mask resister 1 is employed to mask the data signal.

The address signal input buffer circuit 14 generates the mask resister selection signal which includes the instruction to output the mask pattern signals DM0 to DM15 stored in the mask resister 1 provided in the mask resister circuit 11 by using the decoded result, so as to output the generated mask resister selection signal to the mask resister circuit 11.

The mask resister circuit 11 outputs the mask pattern signals DM0 to DM15 stored in the mask resister 1 to the read data converter circuit 16c, based on the mask address selection signal input from the address signal input buffer circuit 14. As shown in FIG. 5, the mask resister 1 stores the data signal of “HLHL . . . HL”. This indicates that the corresponding DQ0, DQ2, DQ4, DQ6, DQ8, DQ10, DQ12, and DQ14 are masked.

The read data converter circuit 16c converts the data signals DQ0 to DQ15 input from the memory cell 500, by using the mask pattern signals DM0 to DM15 input from the mask resister circuit 11, based on the mask control signal input from the data mask signal latch circuit 15. The write data converter circuit 16a outputs the converted data signals DQ0 to DQ15 to the read data buffer circuit 12b. The read data buffer circuit 12b latches the data signals DQ0 to DQ15 input from the read data converter circuit 16c, and amplifies the latched data signals DQ0 to DQ15, so as to output the amplified data signals DQ0 to DQ15 to the data driver circuit 12c.

The data driver circuit 12c reads the data signals DQ0 to DQ15 input from read data buffer circuit 12b at timings of 7, 8, 9, and 10, in synchronization with the transition of the data strobe signal DQS input from the data strobe signal input buffer circuit 13. The data driver circuit 12c amplifies the read data signals DQ0 to DQ15 so as to output the amplified data signals DQ0 to DQ15 to the external input and output terminal 17 of the data signals DQ0 to DQ15.

Therefore, DDR-SDRAM outputs the masked read data signal D1 at the timing of 7, a read data signal D2 at the timing of 8, the masked read data signal D3 at the timing of 9, and a read data signal D4 at the timing of 10, through the external input and output terminal 17 of the data signals DQ0 to DQ15.

In this manner, operation, in which the masked read data signals D1 and D3 are output at the timings of 7 and 9, indicates that the data driver circuit 12c does not operate (in other words, inactivate control), and hence, the corresponding external input and output terminal 17 outputs invalid data such as high-impedance and the like. Thereby, for example, the past record data of the read data signal D2 is maintained at DQ0 in the read data signal D3 at the timing of 9, by a terminating resistor and the like of the semiconductor memory device outside and the like.

### Mask in Read Operation

### EXAMPLE 2

The ACT command is input, and further the row address signal is input through the external input terminals 18 of the address signals AD0 to AD14, at a timing of 11. The read command READ is input, the column address signal is input through the external input terminals 18 of the address signals AD0 to AD14, and further the data mask signals LDM0 to LDM3 are input through the external input terminals 19 of the data mask signals LDM0 to LDM3, at a timing of 13. In this case, (LDM0, LDM 1, LDM2, LDM3)=(L, H, L, H) indicates that a second read data signal D6 (at a timing of 18) and a fourth read data signal D8 (at a timing of 20), which correspond to the read command READ, are masked. The data mask signal latch circuit 15 generates the mask control signal, which controls masking of the second and fourth read data, in accordance with the data mask signals LDM0 to LDM3 read at the timing of 13, so as to output the generated mask control signal to the read data converter circuit 16c.

The address signal input buffer circuit 14 reads the mask instruction signal from the external input terminal 18 of the address signals AD0 to AD14 at a timing of 14. The address signal input buffer circuit 14 decodes the signal of the least significant two bits of the read mask instruction signal, so as to generate the mask resister selection signal which selects the mask resister provided in the mask resister circuit 11. In this case, (AD0, AD1)=(H, H) indicates that the mask pattern signal stored in the mask resister 3 is employed to mask the data signal.

The address signal input buffer circuit 14 generates the mask resister selection signal which includes the instruction to output the mask pattern signals DM0 to DM15 stored in the mask resister 3 provided in the mask resister circuit 11 by using the decoded result, so as to output the generated mask resister selection signal to the mask resister circuit 11.

The mask resister circuit 11 outputs the mask pattern signals DM0 to DM15 stored in the mask resister 3 to the read data converter circuit 16c, based on the mask address selection signal input from the address signal input buffer circuit 14. As shown in FIG. 5, the mask resister 3 stores the data signal of “HHLLLHHHHHLLLHHH”. This indicates that the corresponding DQ0, DQ1, DQ5, DQ6, DQ7, DQ8, DQ9, DQ13, DQ14, and DQ15 are masked.

The read data converter circuit 16c converts the data signals DQ0 to DQ15 input from the memory cell 500, by using the mask pattern signals DM0 to DM15 input from the mask resister circuit 11, based on the mask control signal input from the data mask signal latch circuit 15. The write data converter circuit 16a outputs the converted data signals DQ0 to DQ15 to the read data buffer circuit 12b. The read data buffer circuit 12b latches the data signals DQ0 to DQ15 input from the read data converter circuit 16c, and amplifies the latched data signals DQ0 to DQ15, so as to output the amplified data signals DQ0 to DQ15 to the data driver circuit 12c.

The data driver circuit 12c reads the data signals DQ0 to DQ15 input from read data buffer circuit 12b at timings of 17, 18, 19, and 20, in synchronization with the transition of the data strobe signal DQS input from the data strobe signal input buffer circuit 13. The data driver circuit 12c amplifies the read data signals DQ0 to DQ15 so as to output the amplified data signals DQ0 to DQ15 to the external input and output terminal 17 of the data signals DQ0 to DQ15.

Therefore, DDR-SDRAM outputs a read data signal D5 at the timing of 17, the masked read data signal D6 at the timing of 18, a read data signal D7 at the timing of 19, and the masked read data signal D8 at the timing of 20, through the external input and output terminal 17 of the data signals DQ0 to DQ15.

As described above, according to the first embodiment of the present invention, the mask resister circuit 11 is provided, and stores the mask pattern signals DM0 to DM15 input through the external input and output terminal 17 of the data signals DQ0 to DQ15, hence, the semiconductor memory device can be provided, which can selectively and individually mask each bit of the data signals DQ0 to DQ15 during the read and write operations, without further providing an external input terminal to input the mask pattern signals DM0 to DM15.

### Second Embodiment

Hereinbelow with reference to FIG. 5 and FIG. 7 to FIG. 10, a second embodiment of the present invention will be described. In a configuration of the second embodiment of the present invention, the mask operation can be carried out without the external input terminal 19 of the data mask signals LDM0 to LDM3 to select masking or unmasking of the data signal, which is included in the configuration of the first embodiment of the present invention.

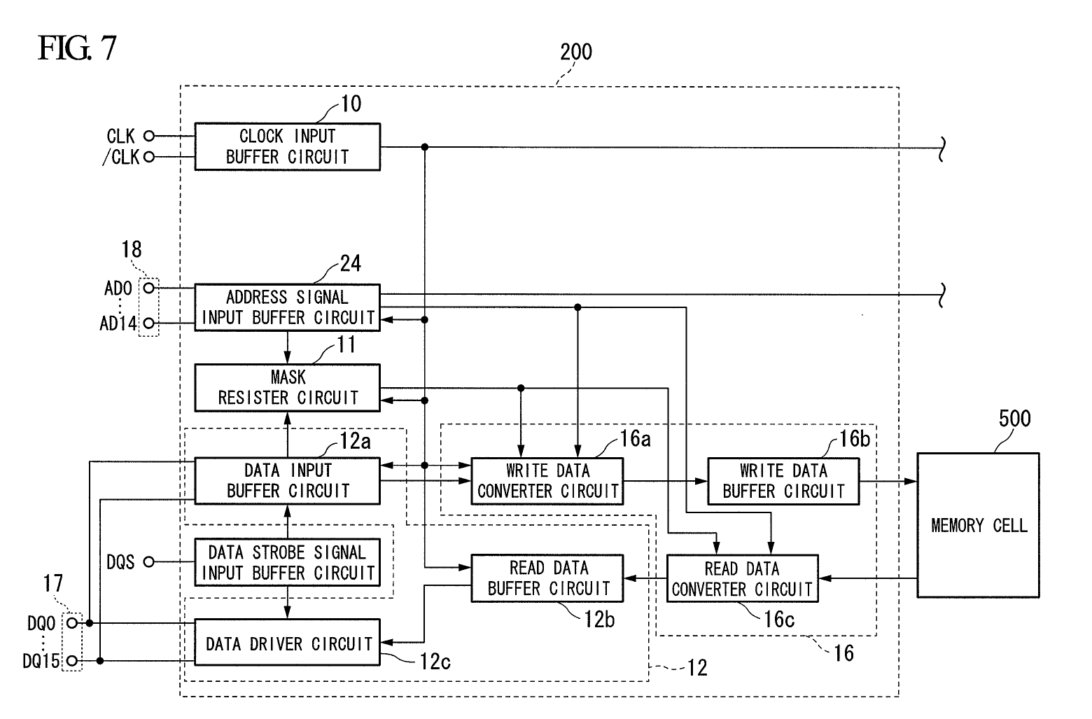

FIG. 7 shows an internal configuration of a data mask portion 200 that relates to input and output of the data signal, and its connecting configuration with the memory cell 500, provided in DDR-SDRAM according to the second embodiment of the present invention.

The configuration according to the second embodiment of the present invention omits the external input terminal 19 of the data mask signals LDM0 to LDM3 from the configuration according to the first embodiment of the present invention.

Furthermore, the data mask portion 200 shown in FIG. 7 has the configuration that omits the data mask signal latch circuit 15 from the configuration according to the first embodiment of the present invention, and substitutes an address signal input buffer circuit 24 for the address signal input buffer circuit 14. The data mask portion 200 has the configuration, in which the mask control signal to control masking of the data signal is output from the address signal input buffer circuit 24 instead of the data mask signal latch circuit 15 according to the first embodiment of the present invention. The other circuits and connecting configuration are the same as the first embodiment of the present invention.

The address signal input buffer circuit 24 amplifies the address signals AD0 to AD14 input from the external input terminal 18 of the address signals AD0 to AD14, so as to output the amplified address signals AD0 to AD14 to the outside of the data mask portion 200. When the MRS command is input to DDR-SDRAM in synchronization with the transition of the clock signal CLK, and further an “H” (high level) is input to the terminals AD13 and AD14 among the external input terminal 18 of the address signals AD0 to AD14, the address signal input buffer circuit 24 decodes the signal of the least significant two bits of a mask instruction signal input through the external input terminal 18 of the address signals AD0 to AD14. The address signal input buffer circuit 24 generates the mask resister selection signal which selects the mask resister provided in the mask resister circuit 11 by using the decoded result, so as to output the generated mask resister selection signal to the mask resister circuit 11. The signal of the least significant two bits of the mask instruction signal correspond to the signals input from terminals corresponding to the address signals AD0 and AD1 among the external input terminal 18 of the address signals AD0 to AD14.

The address signal input buffer circuit 24 decodes the mask instruction signal input through the external input terminal 18 of the address signals AD0 to AD14 in the clock cycle after the write command or the read command is input to DDR-SDRAM. The address signal input buffer circuit 24 generates the mask resister selection signal which selects the mask resister provided in the mask resister circuit 11 by using the decoded result, so as to output the generated mask resister selection signal to the mask resister circuit 11. Furthermore, the address signal input buffer circuit 24 generates the mask control signal by using the decoded result of the signal of the most significant two bits of the mask instruction signal, so as to output the generated mask control signal to the write data converter circuit 16a and the read data converter circuit 16c. The mask control signal generated by the address signal input buffer circuit 24 is the same as the mask control signal generated by the data mask signal latch circuit 15 according to the first embodiment of the present invention, and selects masking or unmasking of the data signal. The most significant two bits of the mask instruction signal correspond to the signals input from terminals corresponding to the address signals AD13 and AD14 among the external input terminal 18 of the address signals AD0 to AD14.

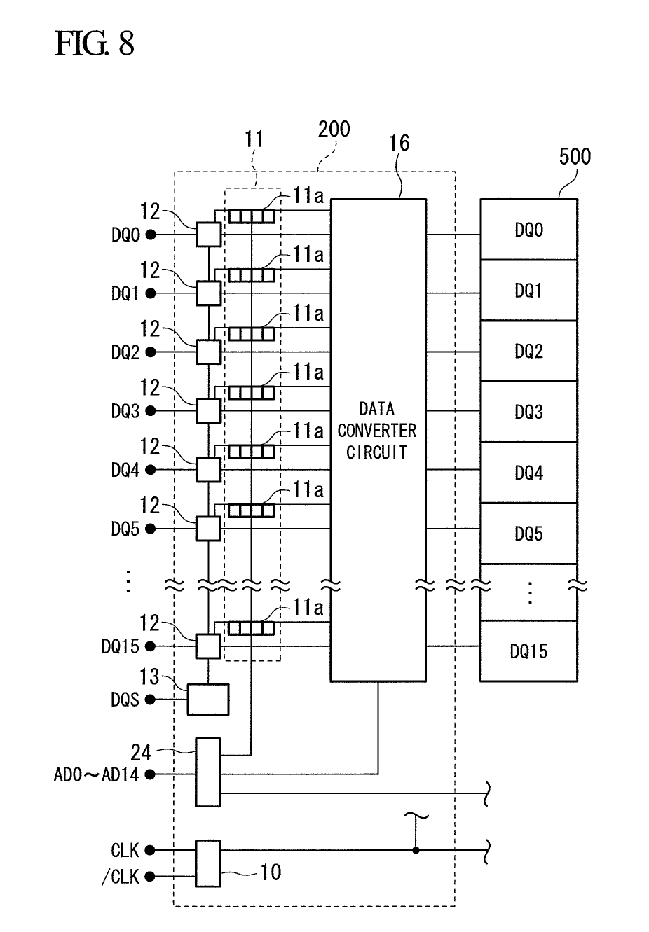

FIG. 8 shows the data mask portion 200 according to the second embodiment of the present invention, in which the mask resister circuit 11a is provided at each external input and output terminal 17 of the data signals DQ0 to DQ15.

As shown in FIG. 8, the mask resister circuit 11 includes 16 pieces of the mask resister circuit 11a therein, which is placed at each external input and output terminal of the data signals DQ0 to DQ15. The mask resister circuit 11a outputs the signal stored in a mask resister provided therein to the data converter circuit 16, as the mask pattern signal DM, based on the input mask resister selection signal, in the mask operation. The mask resister circuit 11a stores the input data signal DQ in the mask resister selected by the mask resister selection signal input from the address signal input buffer circuit 14, in the update operation of the mask resister provided in its own. The mask resister circuit 11a includes the mask resister having 4 bits, and each bit is assigned to an address 0, an address 1, an address 2, and an address 3. The mask resister provided in the mask resister circuit 11a composes the mask resisters 0 to 3 by making the 16 pieces of mask resister with the same identifier to be one set. That is, the set of bits identified as address 0 composes the mask resister 0, the set of bits identified as address 1 composes the mask resister 1, the set of bits identified as address 2 composes the mask resister 2, and the set of bits identified as address 3 composes the mask resister 3.

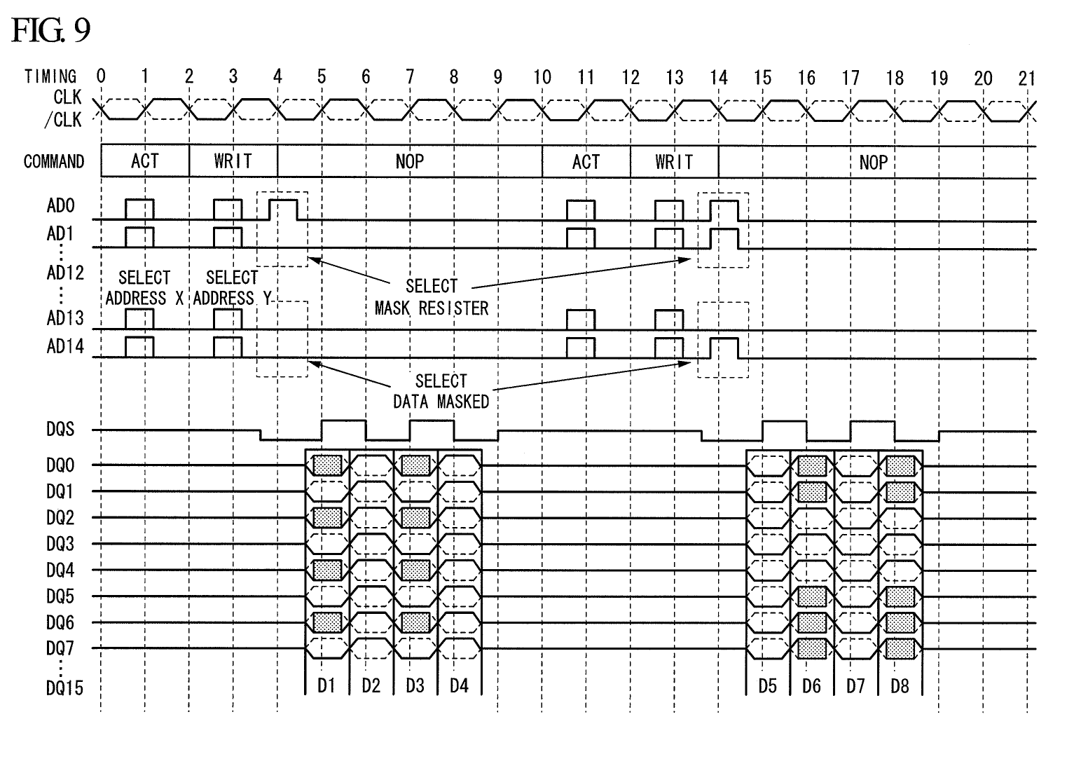

Subsequently, FIG. 9 shows a timing chart that explains the mask in the write operation according to the second embodiment of the present invention. In this write operation, the mask resister provided in the mask resister circuit 11 is assumed to store the value (bit pattern) of the mask pattern signals DM0 to DM15 shown in FIG. 5 in advance.

### Mask in Write Operation

### EXAMPLE 3

The ACT command is input, and further the row address signal is input through the external input terminals 18 of the address signals AD0 to AD14, at a timing of 1. The write command WRIT is input, and further the column address signal is input through the external input terminals 18 of the address signals AD0 to AD14, at a timing of 3.

The address signal input buffer circuit 24 reads the mask instruction signal from the external input terminal 18 of the address signals AD0 to AD14 at a timing of 4. The address signal input buffer circuit 24 decodes the signal of the least significant two bits of the read mask instruction signal, so as to generate the mask resister selection signal which selects the mask resister provided in the mask resister circuit 11. Furthermore, the address signal input buffer circuit 24 decodes the signal of the most significant two bits of the read mask instruction signal, so as to generate the mask control signal.

In this case, (AD0, AD1)=(H, L) indicates that the mask pattern signal stored in the mask resister 1 is employed to mask the data signal. On the other hand, (AD13, AD14)=(L, L) indicates that a first write data signal D1 (at a timing of 5) and a third write data signal D3 (at a timing of 7), which correspond to the write command WRIT, are masked.

The address signal input buffer circuit 24 generates the mask resister selection signal which includes an instruction to output the mask pattern signals DM0 to DM15 stored in the mask resister 1 provided in the mask resister circuit 11 by using the decoded result, so as to output the generated mask resister selection signal to the mask resister circuit 11. Furthermore, the address signal input buffer circuit 24 generates the mask control signal which controls masking of the first and third write data by using the decoded result, so as to output the generated mask control signal to the write data converter circuit 16a.

The mask resister circuit 11 outputs the mask pattern signals DM0 to DM15 stored in the mask resister 1 to the write data converter circuit 16a, based on the mask address selection signal input from the address signal input buffer circuit 24. As shown in FIG. 5, the mask resister 1 stores the data signal of “HLHL . . . HL”. This indicates that the corresponding DQ0, DQ2, DQ4, DQ6, DQ8, DQ10, DQ12, and DQ14 are masked.

The data input buffer circuit 12a reads the data signals DQ0 to DQ15 at timings of 5, 6, 7, and 8, in synchronization with the transition of the data strobe signal DQS input from the data strobe signal input buffer circuit 13. The data input buffer circuit 12a amplifies the read data signals DQ0 to DQ15 so as to output the amplified data signals DQ0 to DQ15 to the write data converter circuit 16a.

The write data converter circuit 16a converts the data signals DQ0 to DQ15 input from the data input buffer circuit 12a, by using the mask pattern signals DM0 to DM15 input from the mask resister circuit 11, based on the mask control signal input from the address signal input buffer circuit 24. The write data converter circuit 16a outputs the converted data signals DQ0 to DQ15 to the write data buffer circuit 16b. The write data buffer circuit 16b amplifies the data signals DQ0 to DQ15 input from the write data converter circuit 16a so as to output the amplified data signals DQ0 to DQ15 to the memory cell 500.

Therefore, the masked write data signal D1, a write data signal D2, the masked write data signal D3, and a write data signal D4 are stored in the memory cell 500.

### Mask in Write Operation

### EXAMPLE 4

The ACT command is input, and further the row address signal is input through the external input terminals 18 of the address signals AD0 to AD14, at a timing of 11. The write command WRIT is input, and further the column address signal is input through the external input terminals 18 of the address signals AD0 to AD14, at a timing of 13.

The address signal input buffer circuit 24 reads the mask instruction signal from the external input terminal 18 of the address signals AD0 to AD14 at a timing of 14. The address signal input buffer circuit 24 decodes the signal of the least significant two bits of the read mask instruction signal, so as to generate the mask resister selection signal which selects the mask resister provided in the mask resister circuit 11. Furthermore, the address signal input buffer circuit 24 decodes the signal of the most significant two bits of the read mask instruction signal, so as to generate the mask control signal. In this case, (AD0, AD1)=(H, H) indicates that the mask pattern signal stored in the mask resister 3 is employed to mask the data signal. On the other hand, (AD13, AD14)=(L, H) indicates that a second write data signal D6 (at a timing of 16) and a fourth write data signal D8 (at a timing of 18), which correspond to the write command WRIT, are masked.

The address signal input buffer circuit 24 generates the mask resister selection signal which includes the instruction to output the mask pattern signals DM0 to DM15 stored in the mask resister 3 provided in the mask resister circuit 11 by using the decoded result, so as to output the generated mask resister selection signal to the mask resister circuit 11. Furthermore, the address signal input buffer circuit 24 generates the mask control signal which controls masking of the second and fourth write data by using the decoded result, so as to output the generated mask control signal to the write data converter circuit 16a.

The mask resister circuit 11 outputs the mask pattern signals DM0 to DM15 stored in the mask resister 3 to the write data converter circuit 16a, based on the mask address selection signal input from the address signal input buffer circuit 24. As shown in FIG. 5, the mask resister 3 stores the data signal of “HHLLLHHHHHLLLHHH”. This indicates that the corresponding DQ0, DQ1, DQ5, DQ6, DQ7, DQ8, DQ9, DQ13, DQ14, and DQ15 are masked.

The data input buffer circuit 12a reads the data signals DQ0 to DQ15 at timings of 15, 16, 17, and 18, in synchronization with the transition of the data strobe signal DQS input from the data strobe signal input buffer circuit 13. The data input buffer circuit 12a amplifies the read data signals DQ0 to DQ15 so as to output the amplified data signals DQ0 to DQ15 to the write data converter circuit 16a.

The write data converter circuit 16a converts the data signals DQ0 to DQ15 input from the data input buffer circuit 12a, by using the mask pattern signals DM0 to DM15 input from the mask resister circuit 11, based on the mask control signal input from the address signal input buffer circuit 24. The write data converter circuit 16a outputs the converted data signals DQ0 to DQ15 to the write data buffer circuit 16b. The write data buffer circuit 16b amplifies the data signals DQ0 to DQ15 input from the write data converter circuit 16a so as to output the amplified data signals DQ0 to DQ15 to the memory cell 500.

Therefore, a write data signal D5, the masked write data signal D6, a write data signal D7, and the masked write data signal D8 are stored in the memory cell 500.

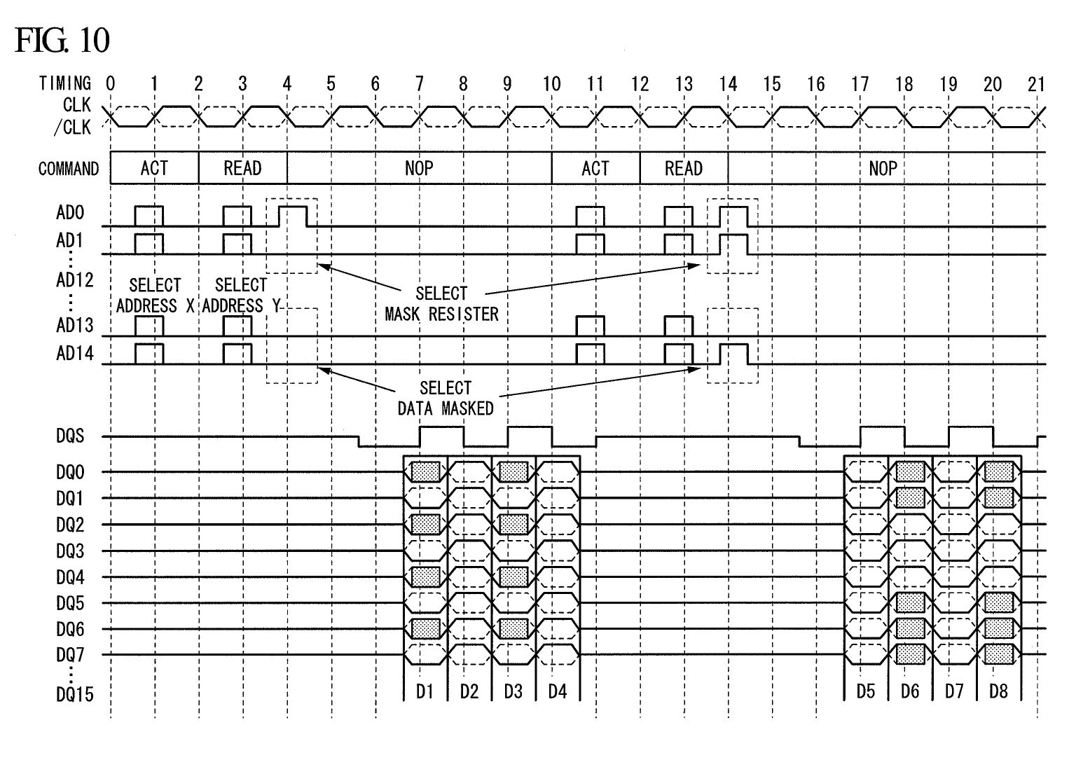

Subsequently, FIG. 10 shows a timing chart that explains the mask in the read operation according to the first embodiment of the present invention. In this read operation, the mask resister provided in the mask resister circuit 11 is assumed to store the value (bit pattern) of the mask pattern signals DM0 to DM15 shown in FIG. 5 in advance.

### Mask in Read Operation

### EXAMPLE 3

The ACT command is input, and further the row address signal is input through the external input terminals 18 of the address signals AD0 to AD14, at a timing of 1. The read command READ is input, and further the column address signal is input through the external input terminals 18 of the address signals AD0 to AD14, at a timing of 3.

The address signal input buffer circuit 24 reads the mask instruction signal from the external input terminal 18 of the address signals AD0 to AD14 at a timing of 4. The address signal input buffer circuit 24 decodes the signal of the least significant two bits of the read mask instruction signal, so as to generate the mask resister selection signal which selects the mask resister provided in the mask resister circuit 11. The address signal input buffer circuit 24 decodes the signal of the most significant two bits of the read mask instruction signal, so as to generate the mask control signal. In this case, (AD0, AD1)=(H, L) indicates that the mask pattern signal stored in the mask resister 1 is employed to mask the data signal. On the other hand, (AD13, AD14)=(L, L) indicates that a first read data signal D1 (at a timing of 7) and a third read data signal D3 (at a timing of 9), which correspond to the read command READ, are masked.

The address signal input buffer circuit 24 generates the mask resister selection signal which includes the instruction to output the mask pattern signals DM0 to DM15 stored in the mask resister 1 provided in the mask resister circuit 11 by using the decoded result, so as to output the generated mask resister selection signal to the mask resister circuit 11. Furthermore, the address signal input buffer circuit 24 generates the mask control signal, which controls masking of the first and third read data, by using the decoded result, so as to output the generated mask control signal to the read data converter circuit 16c.

The mask resister circuit 11 outputs the mask pattern signals DM0 to DM15 stored in the mask resister 1 to the read data converter circuit 16c, based on the mask address selection signal input from the address signal input buffer circuit 24. As shown in FIG. 5, the mask resister 1 stores the data signal of “HLHL . . . HL”. This indicates that the corresponding DQ0, DQ2, DQ4, DQ6, DQ8, DQ10, DQ12, and DQ14 are masked.

The read data converter circuit 16c converts the data signals DQ0 to DQ15 input from the memory cell 500, by using the mask pattern signals DM0 to DM15 input from the mask resister circuit 11, based on the mask control signal input from the address signal input buffer circuit 24. The write data converter circuit 16a outputs the converted data signals DQ0 to DQ15 to the read data buffer circuit 12b. The read data buffer circuit 12b latches the data signals DQ0 to DQ15 input from the read data converter circuit 16c, and amplifies the latched data signals DQ0 to DQ15, so as to output the amplified data signals DQ0 to DQ15 to the data driver circuit 12c.

The data driver circuit 12c reads the data signals DQ0 to DQ15 input from read data buffer circuit 12b at timings of 7, 8, 9, and 10, in synchronization with the transition of the data strobe signal DQS input from the data strobe signal input buffer circuit 13. The data driver circuit 12c amplifies the read data signals DQ0 to DQ15 so as to output the amplified data signals DQ0 to DQ15 to the external input and output terminal 17 of the data signals DQ0 to DQ15.

Therefore, DDR-SDRAM outputs the masked read data signal D1 at the timing of 7, a read data signal D2 at the timing of 8, the masked read data signal D3 at the timing of 9, and a read data signal D4 at the timing of 10, through the external input and output terminal 17 of the data signals DQ0 to DQ15.

### Mask in Read Operation

### EXAMPLE 4

The ACT command is input, and further the row address signal is input through the external input terminals 18 of the address signals AD0 to AD14, at a timing of 11. The read command READ is input, and further the column address signal is input through the external input terminals 18 of the address signals AD0 to AD14, at a timing of 13.

The address signal input buffer circuit 24 reads the mask instruction signal from the external input terminal 18 of the address signals AD0 to AD14 at a timing of 14. The address signal input buffer circuit 24 decodes the signal of the least significant two bits of the read mask instruction signal, so as to generate the mask resister selection signal which selects the mask resister provided in the mask resister circuit 11. The address signal input buffer circuit 24 decodes the signal of the most significant two bits of the read mask instruction signal, so as to generate the mask control signal. In this case, (AD0, AD1)=(H, H) indicates that the mask pattern signal stored in the mask resister 3 is employed to mask the data. On the other hand, (AD13, AD14)=(L, H) indicates that a second read data signal D6 (at a timing of 18) and a fourth read data signal D8 (at a timing of 20), which correspond to the read command READ, are masked.

The address signal input buffer circuit 24 generates the mask resister selection signal which includes the instruction to output the mask pattern signals DM0 to DM15 stored in the mask resister 3 provided in the mask resister circuit 11 by using the decoded result, so as to output the generated mask resister selection signal to the mask resister circuit 11. Furthermore, the address signal input buffer circuit 24 generates the mask control signal, which controls masking of the second and fourth read data, by using the decoded result, so as to output the generated mask control signal to the read data converter circuit 16c.

The mask resister circuit 11 outputs the mask pattern signals DM0 to DM15 stored in the mask resister 3 to the read data converter circuit 16c, based on the mask address selection signal input from the address signal input buffer circuit 24. As shown in FIG. 5, the mask resister 3 stores the data signal of “HHLLLHHHHHLLLHHH”. This indicates that the corresponding DQ0, DQ1, DQ5, DQ6, DQ7, DQ8, DQ9, DQ13, DQ14, and DQ15 are masked.

The read data converter circuit 16c converts the data signals DQ0 to DQ15 input from the memory cell 500, by using the mask pattern signals DM0 to DM15 input from the mask resister circuit 11, based on the mask control signal input from the data mask signal latch circuit 15. The write data converter circuit 16a outputs the converted data signals DQ0 to DQ15 to the read data buffer circuit 12b. The read data buffer circuit 12b latches the data signals DQ0 to DQ15 input from the read data converter circuit 16c, and amplifies the latched data signals DQ0 to DQ15, so as to output the amplified data signals DQ0 to DQ15 to the data driver circuit 12c.

The data driver circuit 12c reads the data signals DQ0 to DQ15 input from read data buffer circuit 12b at timings of 17, 18, 19, and 20, in synchronization with the transition of the data strobe signal DQS input from the data strobe signal input buffer circuit 13. The data driver circuit 12c amplifies the read data signals DQ0 to DQ15 so as to output the amplified data signals DQ0 to DQ15 to the external input and output terminal 17 of the data signals DQ0 to DQ15.

Therefore, DDR-SDRAM outputs a read data signal D5 at the timing of 17, the masked read data signal D6 at the timing of 18, a read data signal D7 at the timing of 19, and the masked read data signal D8 at the timing of 20, through the external input and output terminal 17 of the data signals DQ0 to DQ15.

As described above, according to the second embodiment of the present invention, the mask resister circuit 11 is provided, and stores the mask pattern signals DM0 to DM15 input through the external input and output terminal 17 of the data signals DQ0 to DQ15, hence, the semiconductor memory device can be provided, which can selectively and individually mask each bit of the data signals DQ0 to DQ15 during the read and write operations, without further providing an external input terminal to input the mask pattern signals DM0 to DM15. Furthermore, the data mask portion 200 reads the mask instruction signal via the external input terminal 18 of the address signals AD0 to AD14, and the address signal input buffer circuit 24 is provided, hence, DDR-SDRAM can be provided, which can selectively and individually mask each bit of the data signals DQ0 to DQ15, without the external input terminal 19 of the data mask signals LDM0 to LDM3.

Moreover, a plurality of the mask pattern signals DM0 to DM15 can be employed to mask the data signal during the read operation or the write operation by storing a plurality of the mask pattern signals DM0 to DM15 in the mask resister circuit 11 in advance.

According to the second embodiment of the present invention, the data signals DQ0 to DQ15 to be masked are selected by decoding the signal of the most significant two bits of the mask instruction signal during the mask operation. However, the selection of the data signals DQ0 to DQ15 to be masked may have a variety by using more than two bits. In this manner, a summation of a bit number of the mask instruction signal for selecting the data signals DQ0 to DQ15 to be masked, and a bit number used for selecting the mask resister provided in the mask resister circuit 11, is set not to exceed the terminal number of the external input terminal 18 of the address signals AD0 to AD14.

According to the first and second embodiments of the present invention, the mask resister provided in the mask resister circuit 11 is assumed to include 4 pieces of the resister having the bit width of 16 bits. However, the bit width may be modified in accordance with the terminal number of the external input and output terminal of the data signal.

In addition, the number of the mask resister provided in the mask resister circuit 11 may be modified. In this manner, the summation of the bit number of the mask instruction signal for selecting the data signals DQ0 to DQ15 to be masked, and the bit number used for selecting the mask resister provided in the mask resister circuit 11, is set not to exceed the terminal number of the external input terminal 18 of the address signals AD0 to AD14.

Furthermore, according to the first and second embodiments of the present invention, the address signals AD0 to AD14 are assumed to have a bit width of 15 bits. However, the bit width may be modified in accordance with the storage capacity of the semiconductor memory device.

Moreover, the data mask signals LDM0 to LDM3 may be determined by the mask resister circuit 11, and the mask pattern signals DM0 to DM15 may be determined by the data mask signal latch circuit 15.

That is, in this case, in the semiconductor device that inputs and outputs the bit string of the consecutive data (horizontal axis, or time axis) based on a control signal input from the outside, a semiconductor device, which includes a plurality of input and output terminals corresponding to the bit width of the data input and output (vertical axis), a mask resister circuit that stores a plurality of the mask patterns for individually masking each bit of the bit string (horizontal axis), and a data converter circuit that masks the data by using one of the plurality of the mask patterns and the mask bit string selection signal, wherein one of the plurality of the mask patterns is selected by the mask pattern selection signal, and the mask bit string selection signal selects the bit to be masked in the bit width (vertical axis), is realized so as to achieve an advantageous effect equal to the present application.

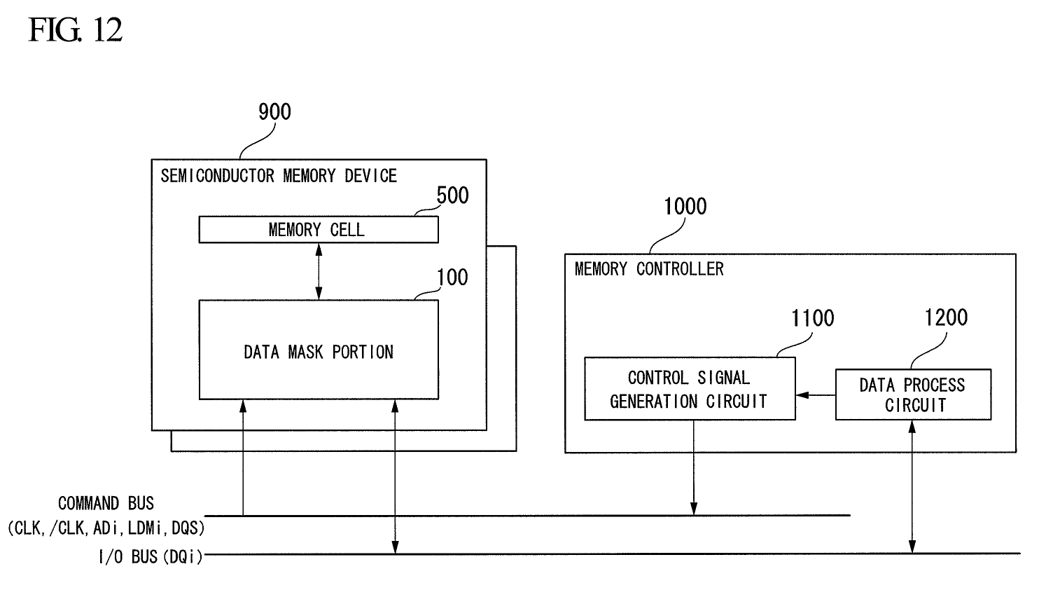

FIG. 12 shows a memory system that includes the semiconductor memory device of the present invention and its memory controller.

A memory controller 1000 is connected with a semiconductor memory device 900 through a command bus and an input and output (I/O) bus. The semiconductor memory device 900 includes a memory cell 500 and a data mask portion 100. The memory controller 1000 includes a control signal generation circuit 1100 and a data process circuit 1200. The memory controller 900 outputs the mode resister set (MRS) command (shown in FIG. 3) generated by the control signal generation circuit 1100 to the command bus, in order to store a plurality of the mask patterns in the mask resister circuit 11 (shown in FIG. 1) provided in the data mask portion 100 in advance. The address signal ADi, which selects one mask pattern from among a plurality of the mask patterns stored in the mask resister circuit 11, is output from the control signal generation circuit 1100 to the command bus, in synchronization with the MRS command. Furthermore, after a predetermined time elapses, the data process circuit 1200 outputs mask pattern information, which corresponds to the mask pattern selected from the I/O bus, to the I/O bus.

The memory controller 1000 outputs the ACT command and a memory command X (shown in FIG. 4) generated by the control signal generation circuit 1100 to the command bus, followed by outputting the write command WRIT and a memory address Y (shown in FIG. 4) generated by the control signal generation circuit 1100 to the command bus, when accessing (writing) to the semiconductor memory device 900. The control signal generation circuit 1100 outputs the bit string mask information (mask bit string selection signal) to the command bus (data mask signal LDMi), in synchronization with the write command WRIT (shown in FIG. 4). Furthermore, after the predetermined time elapses, the control signal generation circuit 1100 outputs the mask pattern selection signal (mask resister instruction signal), which selects one mask pattern from among the plurality of the mask patterns, to the command bus (address signal ADi). In addition, after the predetermined time further elapses, the data process circuit 1200 outputs writing data of being stored in the memory cell 500 to the I/O bus.

The memory controller 1000 outputs the ACT command and the memory command X (shown in FIG. 6) generated by the control signal generation circuit 1100 to the command bus, followed by outputting the read command READ and the memory address Y (shown in FIG. 6) generated by the control signal generation circuit 1100 to the command bus, when accessing to (reading from) the semiconductor memory device 900. The control signal generation circuit 1100 outputs the bit string mask information (mask bit string selection signal) to the command bus (data mask signal LDMi), in synchronization with the read command READ (shown in FIG. 6). Furthermore, after the predetermined time elapses, the control signal generation circuit 1100 outputs the mask pattern selection signal (mask resister instruction signal), which selects one mask pattern from among the plurality of the mask patterns, to the command bus (address signal ADi). In addition, after the predetermined time further elapses, the semiconductor memory device 900 output data read from the memory cell 500 to the I/O bus.

The command bus and the I/O bus are loaded a termination resister (unillustrated) and the like. Among the data read from the semiconductor memory device 900, the I/O bus, which corresponds to the masked data bit, maintains the read data to be past record data, or is transited from the read data of the past record data to a termination voltage value by loading from a power supply connecting with the termination resister. This difference is caused by an accessing frequency of the bit string of the consecutive data. The data driver circuit 12c, which connects with the I/O bus corresponding to the masked data bit, in the semiconductor memory device 900, comes into non-controlled state (that is, high-impedance controlled state by the mask controlling).

According to one advantageous effect of the present invention, the semiconductor device can be provided, which can selectively and individually mask each bit of the consecutive bit string during the read and write operations in the burst mode, without further providing the external input terminal to input the mask pattern signal.

It is apparent that the present invention is not limited to the above embodiments, but may be modified and changed without departing from the scope and spirit of the invention.

Alternately, although the invention has been described above in connection with several preferred embodiments thereof, it will be appreciated by those skilled in the art in that those embodiments are provided solely for illustrating the invention, and should not be relied upon to construe the appended claims in a limiting sense.

What is claimed is:

1. A semiconductor device for inputting and outputting data having a consecutive bit string and a plurality of bit widths based on a control signal input from outside thereof comprising:
a plurality of input and output terminals that corresponds to said bit width of said input and output data;
a mask resister circuit that stores a plurality of mask patterns, in advance, corresponding to information to individually mask or unmask each bit of said bit width; and
a data converter circuit that masks each bit of said input and output data in accordance with one of said plurality of mask patterns and a mask bit string selection signal, wherein:
a mask pattern selection signal selects said one mask pattern from among said plurality of mask patterns stored in said mask resister circuit; and
said mask bit string selection signal controls masking or unmasking of each bit of said consecutive bit string individually based on said control signal.

2. The semiconductor device as recited in claim 1, further comprising:
a first external terminal that inputs a first signal corresponding to said mask pattern selection signal;
a second external terminal that inputs a second signal corresponding to said mask bit string selection signal; and
an external terminal that inputs said plurality of mask patterns stored in said mask resister circuit in advance.

3. The semiconductor device as recited in claim 2, further comprising:
a data mask signal latch circuit that is connected with said second external terminal, wherein
when said consecutive data is input and output, said data mask signal latch circuit reads said second signal corresponding to said mask bit string selection signal from said second external terminal based on said control signal, and instructs to said data converter circuit to individually mask said each bit of said consecutive bit string of said data at each timing of said consecutive data inputting and outputting.

4. The semiconductor device as recited in claim 2, further comprising:
a mask pattern selection signal latch circuit that is connected with said first external terminal,
wherein, when said consecutive data is input and output:
said mask pattern selection signal latch circuit reads said first signal corresponding to said mask pattern selection signal from said first external terminal based on said control signal, and selects said one mask pattern from among said stored plurality of mask patterns; and
said selected one mask pattern instructs to said data converter circuit to individually mask said each bit of said plurality of bit widths of said data at each timing of said consecutive data inputting and outputting.

5. The semiconductor device as recited in claim 2, wherein:
said first signal corresponding to said mask pattern selection signal input to said first external terminal and said second signal corresponding to said mask bit string selection signal input to said second external terminal are input at a timing of said control signal inputting or during a term from said control signal inputting to said data inputting; and
said selected one mask pattern and said mask bit string selection signal are input to said data converter circuit.

6. A semiconductor memory device for inputting and outputting data having a consecutive bit string and a plurality of bit widths to outside thereof comprising:
a plurality of input and output terminals that corresponds to said bit width of said input and output data;
a input and output circuit that inputs and outputs said data, and is connected with said plurality of input and output terminals;
a write circuit and a read circuit that are connected with said input and output circuit, and communicate with a plurality of memory cells;
a mask resister circuit that stores a mask pattern of first information to individually mask or unmask each bit of said bit width; and
a data mask signal generation circuit that generates a mask bit string selection signal of second information to individually mask or unmask each bit of said bit string, wherein:
said mask pattern and said mask bit string selection signal are input to said write circuit and said read circuit; and
said data is input and output by mask controlling in accordance with said mask pattern and said mask bit string selection signal.

7. The semiconductor memory device as recited in claim 6, wherein
said write circuit and said read circuit are activated and inactivated, in accordance with said mask pattern and said mask bit string selection signal.

8. The semiconductor memory device as recited in claim 6, wherein
said input and output circuit is activated and inactivated, in accordance with said mask pattern and said mask bit string selection signal.

9. The semiconductor memory device as recited in claim 6, wherein
said mask resister circuit stores a plurality of said mask patterns, and selects one mask pattern from among said plurality of said mask patterns stored therein based on a control signal input from said outside of said semiconductor memory device.

10. The semiconductor memory device as recited in claim 6, wherein
said mask resister circuit is connected with said input and output terminal or an external address terminal, and stores said mask pattern input from said input and output terminal or said external address terminal based on a control signal input from said outside of said semiconductor memory device.

11. The semiconductor memory device as recited in claim 6, wherein
said data mask signal generation circuit is connected with said input and output terminal or an external address terminal, and inputs said second information to individually mask or unmask each bit of said bit string from said input and output terminal or said external address terminal based on a control signal input from said outside of said semiconductor memory device.

12. A control method of a semiconductor memory device for inputting and outputting data having a consecutive bit string and a plurality of bit widths to outside thereof, said control method comprising:
generating a mask pattern selection signal that selects one mask pattern from among a plurality of said mask patterns, wherein said mask pattern corresponds to first information to individually mask or unmask each bit of said bit width;
generating a mask bit string selection signal that corresponds to second information to individually mask or unmask each bit of said bit string; and
communicating a write circuit and a read circuit, which communicate with a plurality of memory cells, with said memory cell or said semiconductor memory device based on a control signal input from outside of said semiconductor memory device, wherein said write circuit and said read circuit communicate data except individually masked data among said inputting and outputting data to said memory cell or said semiconductor memory device, in accordance with said generated mask pattern selection signal and said generated mask bit string selection signal.

13. The control method as recited in claim 12, wherein
said mask bit string selection signal controls a timing at which said mask pattern signal is applied.

14. The control method as recited in claim 12, wherein:
said write circuit controls to inactivate a write amplifier that corresponds to said masked data during write mode; and
said read circuit controls to inactivate a data driver circuit that is connected with a input and output terminal of said semiconductor memory device, corresponding to said masked data during read mode.

15. A memory system for inputting and outputting data having a consecutive bit string and a plurality of bit widths comprising:
a memory controller and a memory device that input and output said data therebetween; and
a plurality of command buses and a plurality of input and output (I/O) buses that connect said memory controller with said memory device,
wherein:
said memory controller includes a control signal generation circuit and a data process circuit; and
said control signal generation circuit and said data process circuit output selection information that selects necessary command and address to access said memory device, second mask information of said bit string, and a plurality of first mask information of said bit width.

16. The memory system as recited in claim 15, wherein
said control signal generation circuit and said data process circuit store said first and second mask information in said memory device via said command bus and said I/O bus in advance, before accessing a memory cell of said memory device.

17. The memory system as recited in claim 15, wherein
said control signal generation circuit and said data process circuit output said selection information that selects said second mask information of said bit string and said plurality of said first mask information of said bit width via a control terminal except used for selection of said command.

18. The memory system as recited in claim 17, wherein
said first and second mask information and said selection information are output, in synchronization with generation of said command, both after said generation of said command and before output of write-in data to said memory device, or both after said generation of said command and before output of data from said memory device.

19. The memory system as recited in claim 15, wherein
said control signal generation circuit and said data process circuit output said selection information that selects said second mask information of said bit string and said plurality of said first mask information of said bit width via a control terminal used for selection of said command after said generation of said command.

20. The memory system as recited in claim 19, wherein
said first and second mask information and said selection information are output, both after said generation of said command and before output of write-in data to said memory device, or both after said generation of said command and before output of data from said memory device.
